(19) United States
(12) Patent Application Publication
(10) Pub. No.: US 2011/0005824 A1
(43) Pub. Date: Jan. 13, 2011

(54) PRINTED CIRCUIT BOARD AND METHOD OF MANUFACTURING THE SAME

(76) Inventors: Jin Yong AN, Gyunggi-do (KR); Suk Hyeon Cho, Gyunggi-do (KR); Ji Hong Jo, Seoul (KR)

Correspondence Address: BLAKELY SOKOLOFF TAYLOR & ZAFMAN LLP, 1279 OAKMEAD PARKWAY, SUNNYVALE, CA, 94085-4040, US

(21) Appl. No.: 12/544,100

(22) Filed: Aug. 19, 2009

(30) Foreign Application Priority Data
Jul. 7, 2009 (KR) 10-2009-0061553

(51) Int. Cl. H05K 1/11; H05K 3/20

(52) U.S. Cl. 174/261; 29/831

(57) ABSTRACT

This invention relates to a printed circuit board and a method of manufacturing the same, in which an outermost layer of the printed circuit board includes a fine circuit and the manufacturing cost of the printed circuit board is reduced.

### CROSS REFERENCE TO RELATED APPLICATION

This application claims the benefit of Korean Patent Application No. 10-2009-0061553, filed Jul. 7, 2009, entitled “A printed circuit board and a method of manufacturing the same”, which is hereby incorporated by reference in its entirety into this application.

### BACKGROUND OF THE INVENTION

1. Technical Field

The present invention relates to a printed circuit board (PCB) and a method of manufacturing the same.

2. Description of the Related Art

Typically, a PCB is manufactured in such a manner that a wiring pattern is formed using copper foil on either or both surfaces of a board made of any type of thermosetting synthetic resin, after which IC or electronic components are disposed and fixed on the board, electrically wired to each other and then coated with an insulator.

With the recent trend of drastically increasing the processing speed of a digital product, a package substrate used for the digital product has not only high-density electronic components including LSI (Large Scale Integration), IC chips and chip capacitors, which are mounted on the package substrate, but also connector terminals the number of which is increased to satisfy high integration, and the size thereof is gradually reduced. This means requiring high-density wiring and slimness of the package substrate.

In order to fulfill the requirement of high-density wiring, a process of forming a multilayered structure composed of insulating and circuit layers to thus result in a build-up layer is employed.

Also, in order to fulfill the requirement of slimness, a coreless substrate without the use of a core substrate is receiving attention. The coreless substrate may reduce the total thickness of a PCB and thus may shorten signal processing time.

However, the use of the build-up layer or the coreless substrate according to conventional techniques can no longer keep up with a desired processing speed of a digital product.

Hence, an imprinting process is employed to form a trench in order to obtain a fine circuit. However, when the circuit is formed from the entire build-up layer using the imprinting process, the fabrication cost of the PCB is undesirably increased.

### SUMMARY OF THE INVENTION

Accordingly, the present invention has been made keeping in mind the problems encountered in the related art and the present invention intends to provide a PCB and a method of manufacturing the same, in which an outermost layer of the PCB includes a fine circuit and the manufacturing cost of the PCB is reduced.

An aspect of the present invention provides a PCB, including a build-up layer including a build-up insulating layer, a lower circuit layer embedded in a lower surface of the build-up insulating layer, and a first circuit layer formed on an upper surface of the build-up insulating layer and having a first via; and an upper insulating layer formed on the build-up layer and including a second circuit layer which is embedded therein and has a connection pad.

In the aspect, the PCB may further include a second via for electrically connecting the first circuit layer and the second circuit layer to each other.

In the aspect, the first via and the second via have the same shape the diameter of which is reduced downward.

In the aspect, the connection pad may have an exposed surface which is flush with a surface of the upper insulating layer.

In the aspect, the PCB may further include a solder resist layer formed on the upper insulating layer and having an opening for exposing the connection pad.

In the aspect, a width of the connection pad may be equal to a width of the opening.

Another aspect of the present invention provides a method of manufacturing the PCB, including (A) forming a lower circuit layer on one surface of a support; (B) forming on the support a build-up layer including a build-up insulating layer and a first circuit layer formed on the build-up insulating layer and having a first via; (C) forming an upper insulating layer on the build-up layer; (D) pressing a carrier including a second circuit layer having a connection pad on the upper insulating layer, thus embedding the second circuit layer in the upper insulating layer; and (E) removing the carrier.

After (E), the method may further include forming a second via for electrically connecting the first circuit layer and the second circuit layer to each other.

The first via and the second via may be formed to have the same shape the diameter of which is reduced downward.

In (D), the second circuit layer may be embedded in the upper insulating layer so that an exposed surface of the connection pad is flush with a surface of the upper insulating layer.

Also, after (E), the method may further include forming a solder resist layer having an opening for exposing the connection pad on the upper insulating layer.

The solder resist layer may be formed on the upper insulating layer so that a width of the connection pad is equal to a width of the opening.

### BRIEF DESCRIPTION OF THE DRAWINGS

The features and advantages of the present invention will be more clearly understood from the following detailed description taken in conjunction with the accompanying drawings, in which:

FIGS. 1 to 7 are cross-sectional views sequentially showing a process of manufacturing a PCB according to an embodiment of the present invention.

### DESCRIPTION OF SPECIFIC EMBODIMENTS

Hereinafter, a detailed description will be given of a PCB and a method of manufacturing the PCB according to embodiments of the present invention with reference to the accompanying drawings. Throughout the drawings, the same reference numerals refer to the same or similar elements, and redundant descriptions are omitted. In the description, the terms “upper”, “lower”, “first”, “second” and so on are used only to distinguish one element from another element, and the elements are not defined by the above terms.

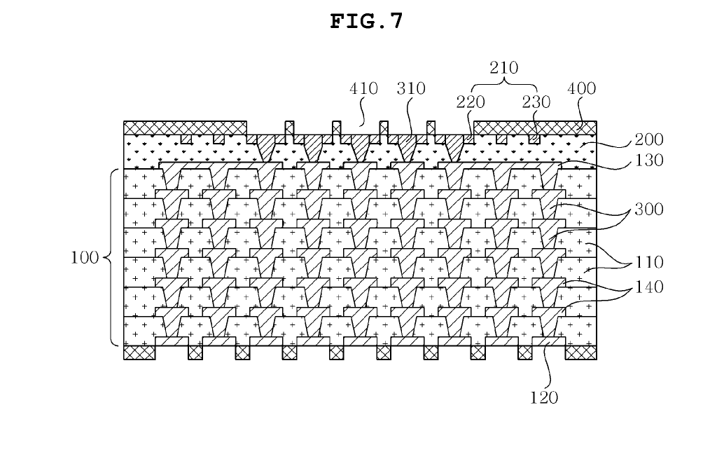

FIG. 7 is a cross-sectional view showing a PCB according to an embodiment of the present invention. As shown in FIG. 7, the PCB according to the present embodiment includes a build-up layer 100 composed of a build-up insulating layer 110, a lower circuit layer 120 embedded in the lower surface of the build-up insulating layer 110 and a first circuit layer 130 formed on the upper surface of the build-up insulating layer 110 and having first vias 300, and an upper insulating layer 200 formed on the build-up layer 100 and having a second circuit layer 210 which is embedded therein and includes a connection pad 220.

The build-up insulating layer 110 may be made of a composite polymer resin which is typically used as an interlayer insulating material. For example, a prepreg may be used as the build-up insulating layer 110, so that the PCB is made thinner. Alternatively, ABF (Ajinomoto Build-up Film) may be used as the build-up insulating layer 110, thus facilitating the formation of a fine circuit. In addition, an example of a material for the build-up insulating layer 110 may include but is not limited to an epoxy-based resin, such as FR-4, BT (Bismaleimide Triazine) or the like.

The upper insulating layer 200 is formed on the build-up insulating layer 110, and includes the second circuit layer 210 embedded in the upper surface thereof. Like the build-up insulating layer 110, the upper insulating layer 200 may be formed using an epoxy-based resin, including a prepreg, ABF, FR-4, BT or the like, which is the composite polymer resin.

The lower circuit layer 120 is embedded in the lower surface of the build-up insulating layer 110, and particularly, the exposed surface of the lower circuit layer 120 is flush with the surface of the build-up insulating layer 110. Also, the lower circuit layer 120 may be electrically connected to the first circuit layer 130 through the first vias 300, if needed.

The first circuit layer 130 is formed on the upper surface of the build-up insulating layer 110. As shown in FIG. 7, the first circuit layer 130 may be formed to protrude from the upper surface of the build-up insulating layer 110, and is embedded in the lower surface of the upper insulating layer 200. However, the first circuit layer 130 need not be essentially formed to protrude. In the case where the first circuit layer is planarized through grinding or etching, the protrusion thereof is removed and thus the first circuit layer may not be embedded in the upper insulating layer 200.

The first circuit layer 130 includes the first vias 300 for electrically connecting it to the lower circuit layer 120. In the present embodiment, the first vias 300 are illustrated in the form of a multilayer, but the first vias 300 may be provided in the form of a monolayer depending on the stacked configuration of the build-up layer 100. For example, inner circuit layers 140 may be formed in the build-up layer 100 depending on needs. If the inner circuit layers 140 are present, the first vias 300 are provided in the form of a multilayer. On the other hand, if the inner circuit layers 140 are absent, the first vias 300 are provided in the form of a monolayer.

The second circuit layer 210 is embedded in the upper surface of the upper insulating layer 200, and is an outermost circuit layer of the PCB and thus includes the connection pad 220 for electrically connecting it to an electronic component which is to be subsequently mounted on the PCB. The exposed surface of the connection pad 220 may be flush with the surface of the upper insulating layer 200. When the exposed surface of the connection pad 220 and the surface of the upper insulating layer 200 are flush with each other, the surface of the PCB becomes planarized, thus preventing the formation of voids in an underfill process and increasing mounting efficiency of ICs and then a mother board.

Furthermore, the second circuit layer 210 may include a circuit pattern 230. As such, it is optional that the second circuit layer 210 be formed to include the circuit pattern 230. Specifically, when the second circuit layer 210 is patterned, whether the circuit pattern 230 is formed or not may be determined.

The second vias 310 are located between the first circuit layer 130 and the second circuit layer 210, and play a role in electrically connecting the first circuit layer 130 and the second circuit layer 210 to each other.

In the present invention, the first vias 300 and the second vias 310 may have the same shape the diameter of which is reduced downward (FIG. 7). This shape is typically obtained when processing vias using CO₂, YAG, excimer laser or the like. However, the present invention is not necessarily limited to the vias processed using the laser as above, but any processing method may be applied as long as the resultant first and second vias 300, 310 have a shape the diameter of which is reduced downward, which should also be incorporated in the scope of the present invention.

The lower circuit layer 120, the first circuit layer 130, the second circuit layer 210, the inner circuit layers 140, the first vias 300 and the second vias 310 may be made of an electrically conductive metal such as gold, silver, copper, nickel or the like, in order to electrically connect them to each other.

Also, in order to protect the PCB, a solder resist layer 400 may be disposed on the second circuit layer 210. The solder resist layer 400 has an opening 410 enabling the electrical connection of the connection pad 220 to an electronic component which is to be subsequently mounted on the PCB. As such, the width of the connection pad 220 is made equal to that of the opening 410, thus facilitating the electrical connection between the connection pad 220 and the mounted electronic component.

FIGS. 1 to 7 sequentially show the process of manufacturing the PCB according to the embodiment of the present invention. Below, the method of manufacturing the PCB according to the present embodiment is specified with reference to the above drawings.

In the present embodiment, the formation of the PCB only on one surface of a support 500 is illustrated, but it will also be understood that the PCB may be formed on both surfaces of the support 500.

First, as shown in FIG. 1, the support 500 is prepared, and the lower circuit layer 120 is formed on one surface of the support 500. The support 500 prevents the warping of the PCB during the manufacturing process, and may include a release layer on the surface thereof in order to separate the PCB from the support 500 after completion of a stacking process.

The support 500 is formed of a hard material able to support the build-up layer 100, and an example thereof may include but is not limited to a metal plate or a prepreg. In addition, the support 500 may be made of a hard insulating material, including epoxy resin, modified epoxy resin, bisphenol A resin, epoxy-novolac resin, or aramid-, glass fiber- or paper-reinforced epoxy resin.

The release layer may be a typical film type release material or foam tape, and may be formed through thin film coating or sputtering.

In the present step, the lower circuit layer 120 may be obtained by forming a plating layer on one surface of the support 500 through electroless plating/electroplating and then patterning the plating layer.

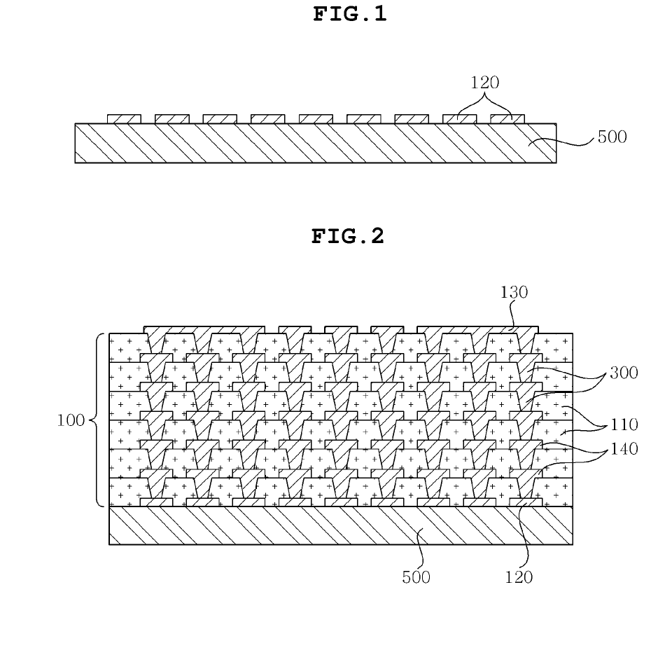

Next, as shown in FIG. 2, provided on the support 500 having the lower circuit layer 120 is the build-up layer 100 including the build-up insulating layer 110 and the first circuit layer 130 formed on the build-up insulating layer 110 and including the first vias 300. The build-up process may include typical stacking and circuit patterning, and a typical process for forming the build-up layer 100 is not specified herein. As such, the first vias 300 may be processed using CO₂, YAG or excimer laser so as to have a shape the diameter of which is reduced downward. As mentioned above, in the present embodiment, the build-up layer 100 including a plurality of inner circuit layers 140 and multilayered first vias 300 is illustrated, but the present invention is not limited thereto. Alternatively, the inner circuit layers 140 may not be provided and the first vias 300 may be provided in the form of a monolayer.

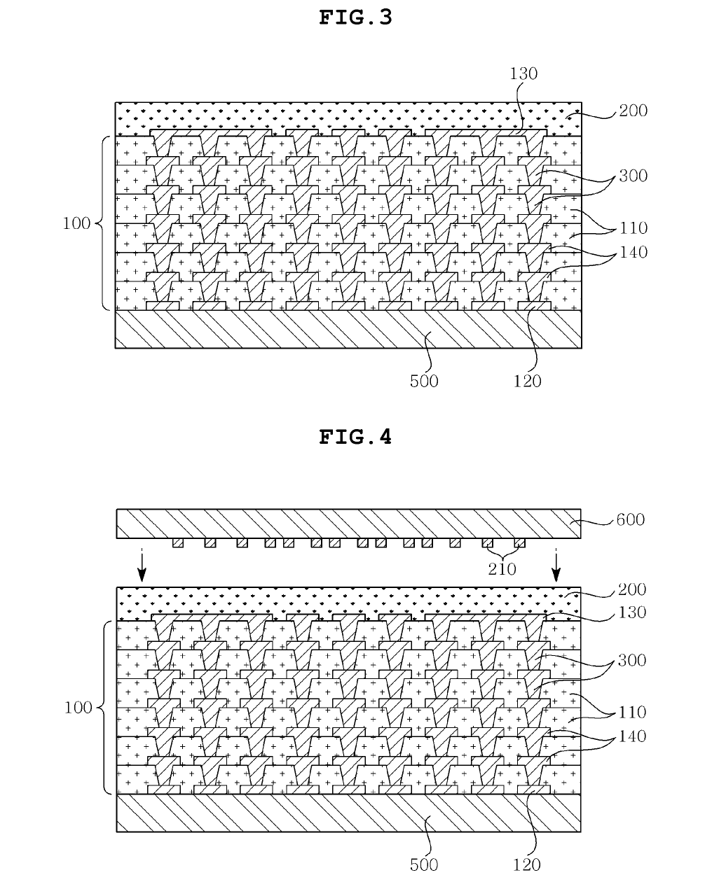

Next, as shown in FIG. 3, the upper insulating layer 200 is formed on the build-up layer 100. The first circuit layer 130 is embedded in the upper insulating layer 200.

Next, as shown in FIG. 4, a carrier 600 having the second circuit layer 210 is pressed on the upper insulating layer 200, so that the second circuit layer 210 is embedded in the upper insulating layer 200. In the present embodiment, the carrier 600 may be a metal carrier. The second circuit layer 210 may be formed by plating one surface of the carrier 600 with a conductive material such as a metal.

The carrier 600 may be made of glass or a polymer, and the process of forming the second circuit layer 210 may vary depending on the type of material for the carrier 600. For example, in the case where the carrier is made of glass, the second circuit layer 210 may be formed by preparing a plating layer through electroless plating/electroplating and then patterning the plating layer. The second circuit layer 210 thus formed is embedded by pressing the carrier 600 on the upper insulating layer 200.

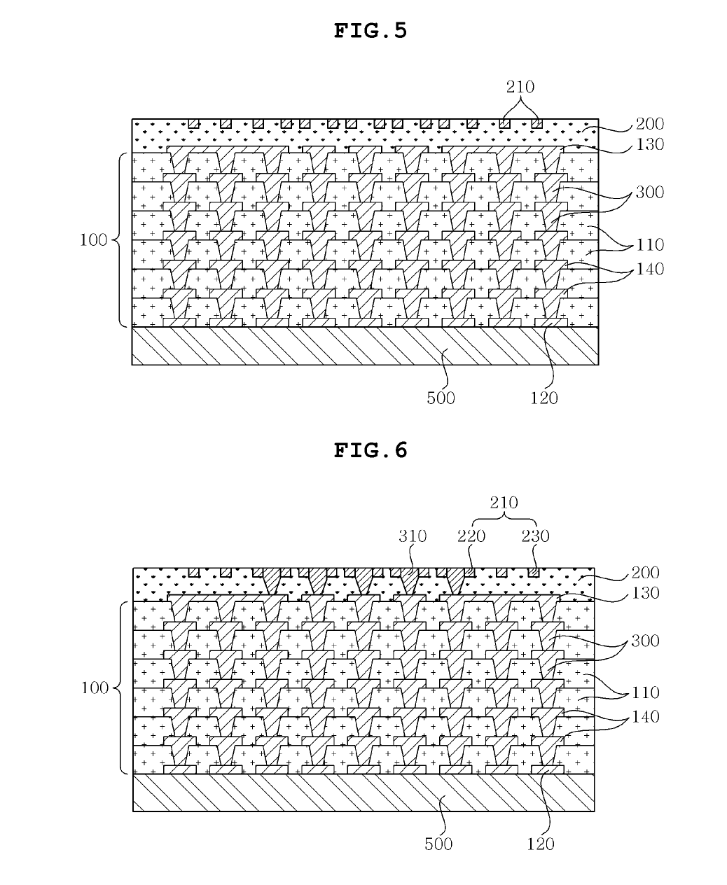

Next, as shown in FIG. 5, the carrier 600 is removed. The carrier 600 may be removed through etching. Because the second circuit layer 210 is embedded in the upper insulating layer 200, even when an etching process is performed, an under-cut problem of a protruding circuit layer does not occur. Therefore, a finer circuit may be obtained compared to conventional techniques. Also, the second circuit layer 210 is completely embedded in the upper insulating layer 200, whereby the exposed surface of the connection pad 220 included in the second circuit layer 210 may be flush with the surface of the upper insulating layer 200.

Next, as shown in FIG. 6, the second vias 310 for electrically connecting the first circuit layer 130 and the second circuit layer 210 to each other are formed. As in the processing of the first vias 300, the second vias 310 may be processed using CO₂, YAG or excimer laser so as to have a shape the diameter of which is reduced downward. Thus, the first vias 300 and the second vias 310 may have the same shape the diameter of which is reduced downward.

The second vias 310 are filled with a conductive material such as a metal using a plating process in order to electrically connect the first circuit layer 130 and the second circuit layer 210 to each other.

Next, as shown in FIG. 7, the solder resist layer 400 having the opening 410 for exposing the connection pad 220 is formed on the upper insulating layer 200. The solder resist layer 400 functions to protect the PCB, and the opening 410 enables the electrical connection of the connection pad 220 to an electronic component which is to be subsequently mounted on the PCB.

Also, because the second circuit layer 210 is completely embedded in the upper insulating layer 200, the upper surface of the upper insulating layer 200 is flat, thus making it easy to form the solder resist layer 400 on the upper insulating layer 200 so that the width of the connection pad 220 and the width of the opening 410 are equal to each other. When the width of the connection pad 220 is equal to the width of the opening 410, the electrical connection between the connection pad and the electronic component becomes easier.

As described hereinbefore, the present invention provides a PCB and a method of manufacturing the same. According to the present invention, an outermost layer of the PCB is formed through an imprinting process, resulting in a fine circuit. The circuit of the outermost layer is embedded, thus increasing mounting efficiency of ICs and then a mother board.

Although the embodiments of the present invention regarding the PCB and the method of manufacturing the same have been disclosed for illustrative purposes, those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

What is claimed is:

1. A printed circuit board, comprising:
a build-up layer, including a build-up insulating layer, a lower circuit layer embedded in a lower surface of the build-up insulating layer, and a first circuit layer formed on an upper surface of the build-up insulating layer and having a first via; and
an upper insulating layer formed on the build-up layer and including a second circuit layer which is embedded therein and has a connection pad.

2. The printed circuit board as set forth in claim 1, further comprising a second via for electrically connecting the first circuit layer and the second circuit layer to each other.

3. The printed circuit board as set forth in claim 2, wherein the first via and the second via have a same shape a diameter of which is reduced downward.

4. The printed circuit board as set forth in claim 1, wherein the connection pad has an exposed surface which is flush with a surface of the upper insulating layer.

5. The printed circuit board as set forth in claim 1, further comprising a solder resist layer formed on the upper insulating layer and having an opening for exposing the connection pad.

6. The printed circuit board as set forth in claim 5, wherein a width of the connection pad is equal to a width of the opening.

7. A method of manufacturing a printed circuit board, comprising:
(A) forming a lower circuit layer on one surface of a support;
(B) forming on the support a build-up layer including a build-up insulating layer and a first circuit layer formed on the build-up insulating layer and having a first via;
(C) forming an upper insulating layer on the build-up layer;
(D) pressing a carrier including a second circuit layer having a connection pad on the upper insulating layer, thus embedding the second circuit layer in the upper insulating layer; and
(E) removing the carrier.

8. The method as set forth in claim 7, further comprising forming a second via for electrically connecting the first circuit layer and the second circuit layer to each other, after (E).

9. The method as set forth in claim 8, wherein the first via and the second via are formed to have a same shape a diameter of which is reduced downward.

10. The method as set forth in claim 7, wherein, in (D), the second circuit layer is embedded in the upper insulating layer so that an exposed surface of the connection pad is flush with a surface of the upper insulating layer.

11. The method as set forth in claim 7, further comprising forming a solder resist layer having an opening for exposing the connection pad on the upper insulating layer, after (E).

12. The method as set forth in claim 11, wherein the solder resist layer is formed on the upper insulating layer so that a width of the connection pad is equal to a width of the opening.
